(19) United States
(12) Patent Application Publication
(10) Pub. No.: US 2026/0282205 A1
(43) Pub. Date: Sep. 17, 2026

(54) MODULE CARD AS WELL AS COMBINATION OF MODULE CARD AND SLOT

(71) Applicant: Orient Semiconductor Electronics, Limited, Kaohsiung City (TW)

(72) Inventors: YUEH-MING TUNG, Kaohsiung City (TW); Chia-Ming Yang, Kaohsiung City (TW); Hsuan Chang, Kaohsiung City (TW); Ying-Chih Lee, Kaohsiung City (TW); Tsun-Lung Hsieh, Kaohsiung City (TW); Yu-Chen Lin, Kaohsiung City (TW); Lan-Kuei Chen, Kaohsiung City (TW); Po-Yen Yen, Kaohsiung City (TW)

(21) Appl. No.: 19/241,607

(22) Filed: Jun. 18, 2025

(30) Foreign Application Priority Data
Mar. 17, 2025 (TW) 114109930

(51) Int. Cl. H05K 1/02; H05K 5/02

(52) U.S. Cl. CPC H05K 1/0203; H05K 5/0286; H05K 2201/10159

(57) ABSTRACT

The present disclosure provides a module card and its combination with a slot. The module card of the present disclosure includes a substrate, a first die, a second die, adhesive, a plurality of metal contacts, a heat-conducting layer and a thermally conductive material. The substrate has opposing first surface and second surface. A plurality of through holes is formed in the substrate. The through holes penetrate the substrate from the first surface to the second surface. The first die and the second die are disposed on the first surface of the substrate. The adhesive is used to attach the second die to the first surface of the substrate. The metal contacts are disposed on the second surface of the substrate. The heat-conducting layer is disposed on the second surface of the substrate. The thermally conductive material is filled in the through holes and is in contact with the adhesive and the heat-conducting layer.

### CROSS-REFERENCE TO RELATED APPLICATIONS

The present application is based on and claims priority to Taiwanese Application Number 114109930, filed Mar. 17, 2025, the disclosure of which is hereby incorporated by reference herein in its entirety.

### FIELD OF THE DISCLOSURE

This disclosure relates to a module card and its combination with a slot, and more particularly relates to a module card with good heat dissipation capability and its combination with a slot.

### BACKGROUND OF THE DISCLOSURE

At present, the computing speeding of the dies in flash memory cards is getting faster and faster. This causes the temperature on the surfaces of the memory cards to rise continuously and leads to concern about burns for users. Additionally, the increase in temperature for a die may lead to its reduced computing performance, slower data processing speed, and reduced reliability and stability. Furthermore, overheating for a die may cause function failure and even reduce service life. Therefore, it is necessary for a die to use heat dissipation technology to maintain a stable operating temperature.

### SUMMARY

In view of the above, the present disclosure provides a module card and its combination with a slot to solve the above problems.

In one embodiment, the module card of the present disclosure includes a substrate, a first die, a second die, an adhesive, a plurality of metal contacts, a heat-conducting layer and a thermally conductive material. The substrate has opposing first surface and second surface. A die placement area is defined on the first surface. A plurality of through holes is formed in the substrate and penetrates from the first surface through the substrate to the second surface. The first die is disposed on the first surface of the substrate. The second die is disposed in the die placement area. The adhesive is disposed between the second die and the substrate to attach the second die to the first surface of the substrate. The metal contacts are disposed on the second surface of the substrate and are electrically connected to the first die and the second die. The heat-conducting layer is disposed on the second surface of the substrate for contacting a heat-conducting sheet on a slot. The thermally conductive material is filled in the through holes and is in contact with the heat-conducting layer and the adhesive.

In another embodiment, the combination of a module card and a slot includes a slot and the above-mentioned module card. The slot includes a substrate, a plurality of metal contacts and a heat-conducting sheet. The metal contacts are disposed on and electrically connected to the substrate. The heat-conducting sheet is disposed on the substrate. The module card is inserted into the slot. The metal contacts of the slot are in contact with the metal contacts of the module card respectively. The heat-conducting sheet of the slot is in contact with the heat-conducting layer of the module card.

The module card of the present disclosure has good heat dissipation capability and is capable of preventing the temperature on the surface thereof from rising continuously. Therefore, a user will not have a concern about burns.

The foregoing, as well as additional objects, features and advantages of the disclosure will be more readily apparent from the following detailed description, which proceeds with reference to the accompanying drawings.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of the module card according to the present disclosure.

FIG. 2 is a cross-sectional view taken along line A-A in FIG. 1.

FIG. 3 is a cross-sectional view taken along line B-B in FIG. 1.

FIG. 4 is a schematic diagram of the slot according to the present disclosure.

FIG. 5 is a cross-sectional view taken along line C-C in FIG. 4.

FIG. 6 is a schematic diagram of the combination of the module card and the slot according to the present disclosure.

### DETAILED DESCRIPTION OF THE DISCLOSURE

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “Below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

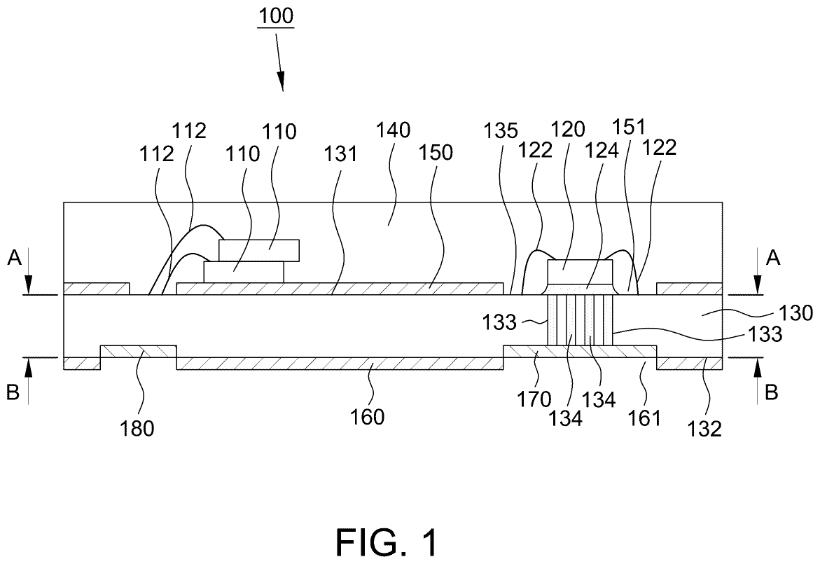

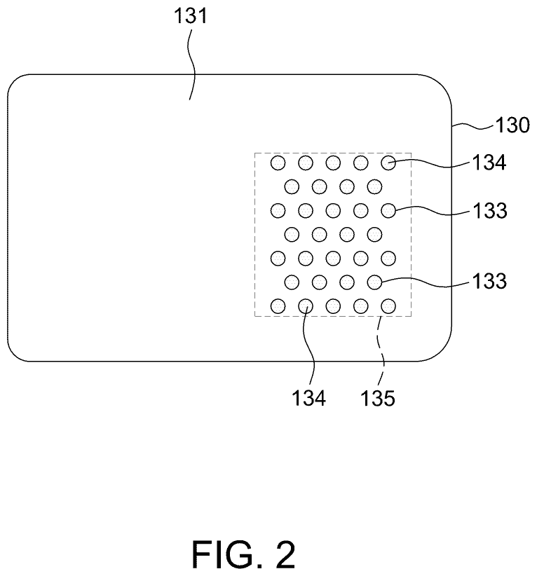

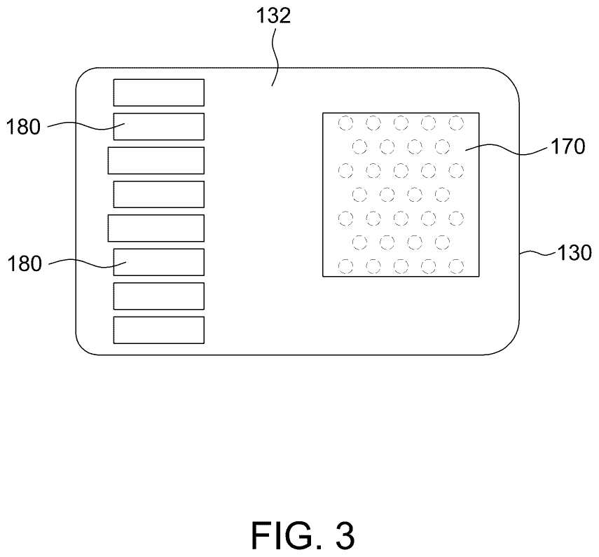

FIG. 1 is a schematic diagram of the module card 100 according to the present disclosure. FIG. 2 is a cross-sectional view taken along line A-A in FIG. 1, where the area enclosed by the dashed line is the die placement area 135. FIG. 3 is a cross-sectional view taken along line B-B in FIG. 1.

Referring to FIGS. 1 to 3, the module card 100 of the present disclosure includes a substrate 130 on which conductive traces are formed (not shown). The substrate 130 has opposing first surface 131 and second surface 132, and the first surface 131 and the second surface 132 are located on different planes. For example, the first surface 131 is a top surface and the second surface 132 is a bottom surface, but is not limited thereto.

In one embodiment, the substrate 130 may be a single-layer or multi-layer circuit board.

The first surface 131 of the substrate 130 is covered by a first solder mask 150. The first solder mask 150 has a first window 151 formed therein to expose the first surface 131 of the substrate 130. A die placement area 135 is defined on the first surface 131 of the substrate 130 and is located in the first window 151. That is, the die placement area 135 is not covered by the first solder mask 150.

The second surface 132 of the substrate 130 is covered by a second solder mask 160. The second solder mask 160 has a second window 161 formed therein to expose the second surface 132 of the substrate 130. A heat-conducting layer 170 is disposed on the second surface 132 of the substrate 130 and is exposed from the second window 161. That is, the heat-conducting layer 170 is not completely covered by the second solder mask 160.

In one embodiment, the heat-conducting layer 170 may be made of thermally conductive material such as gold or copper. The shape of the heat-conducting layer 170 may be circular, rectangular or any other shape.

A plurality of through holes 133 is formed in the substrate 130 and penetrates the substrate 130 from the first surface 130 to the second surface 132. The through holes 133 are located between the die placement area 135 and the second window 161, and are connected to the first window 151 and the second window 161.

The through holes 133 are filled with a thermally conductive material 134, such as gold or copper. The thermally conductive material 134 in the through holes 133 is in contact with the heat-conducting layer 170.

One or more, for example, a plurality of first dies 110 is disposed on the first surface 131 of the substrate 130. The first dies 110 each have an active surface and a back surface opposite to the active surface. The first dies 110 may be stacked vertically or stepwise on the substrate 130 and adhered to the substrate 130 with adhesive or epoxy resin. When the first dies 110 are stacked on the substrate 130 in a stepwise manner, they may be electrically connected to the substrate 130 by means of a plurality of bonding wires 112, i.e. the respective ends of the bonding wires 112 are connected to the active surfaces of the first dies 110 and the substrate 130.

In one embodiment, the first dies 110 may be memory dies.

A second die 120 is disposed on the first surface 131 of the substrate 130. The second die 120 has an active surface and a back surface opposite to the active surface. The back surface of the second die 120 is adhered to the die placement area 135 with a highly thermally conductive adhesive 124, which is in contact with the thermally conductive material 134 in the through holes 133. The highly thermally conductive adhesive 124 is made of a thermally conductive material. The second die 120 may be electrically connected to the substrate 130 by means of a plurality of bonding wires 122.

In one embodiment, the second die 120 may be a die that generates high heat during operation, such as a controller die or a power management die, but the present disclosure is not limited thereto.

A molding compound 140 is formed on the first surface 131 of the substrate 130 to cover and therefore protect the second die 120, the first dies 110, and the bonding wires 112 and 122.

A plurality of metal contacts 180, such as connecting fingers, is disposed on the second surface 132 of the substrate 130. The metal contacts 180 are disposed to expose from the second solder mask 160 and are configured to electrically connect to external circuits.

According to the module card 100 of the present disclosure, the first dies 110 may be electrically connected to the metal contacts 180 through the bonding wires 112 and the conductive traces on the substrate 130. The second die 120 may be electrically connected to the metal contacts 180 through the bonding wires 122 and the conductive traces on the substrate 130. In this way the first dies 110 and the second die 120 may be electrically connected to an external circuit through the metal contacts 180.

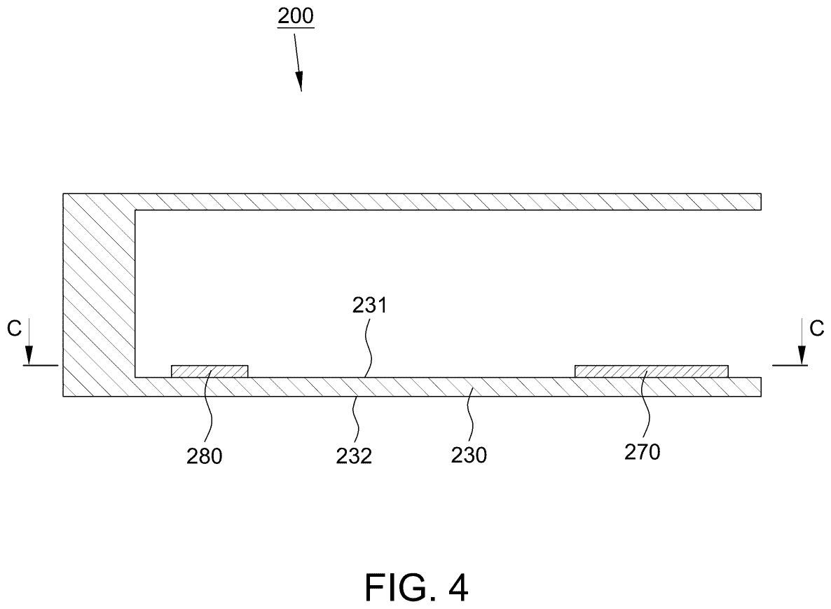

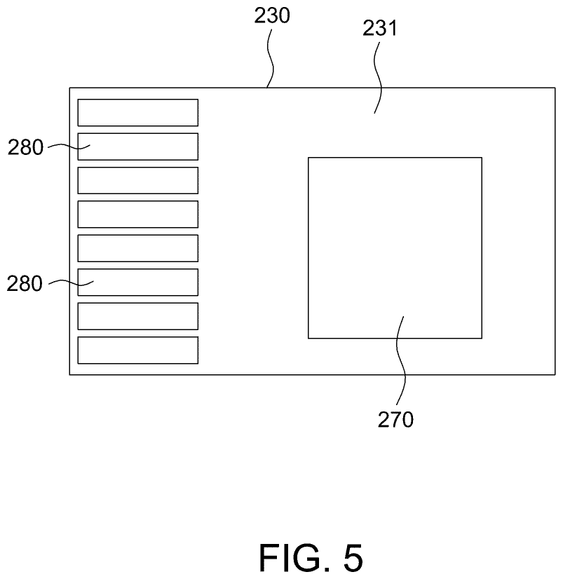

FIG. 4 is a schematic diagram of the slot 200 according to the present disclosure. FIG. 5 is a cross-sectional view taken along line C-C in FIG. 4.

Referring to FIGS. 4 and 5, the slot 200 of the present disclosure includes a substrate 230 on which conductive traces are formed (not shown). The substrate 230 has opposing first surface 231 and second surface 232, and the first surface 231 and the second surface 232 are located on different planes.

A plurality of metal contacts 280 is disposed on and electrically connected to the substrate 230. The metal contacts 280 protrude from the first surface 231 and are configured to contact respectively the metal contacts 180 on the module card 100.

A heat-conducting sheet 270 is disposed on and thermally connected to the substrate 230. The heat-conducting sheet 270 protrudes from the first surface 231. The heat-conducting sheet 270 may be made of metal such as gold or copper, but the present disclosure is not limited thereto.

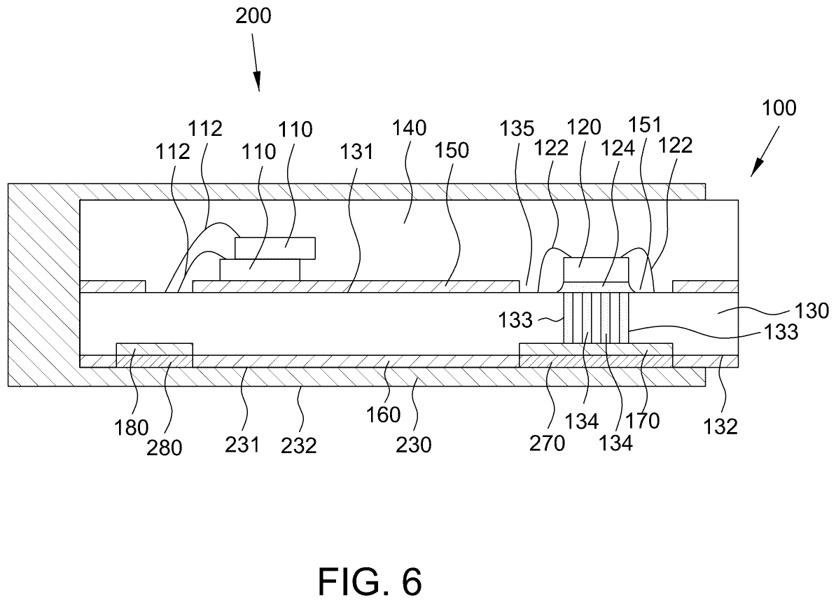

FIG. 6 is a schematic diagram of the combination of the module card 100 and the slot 200 according to the present disclosure.

The slot 200 of the present disclosure may be installed on an electronic device, such as a computer (not shown). Please refer to FIG. 6, when the module card 100 is inserted into the slot 200 in position, the metal contacts 280 will be in direct contact with the metal contacts 180 respectively. In this way, the first dies 110 and the second die 120 may be electrically connected to an external circuit.

According to the module card 100 of the present disclosure, when the module card 100 is inserted into the slot 200 in position, the heat-conducting sheet 270 will be in direct contact with the heat-conducting layer 170 on the module card 100. The heat generated by the second die 120 during operation may be conducted to an external electronic device through the thermally conductive adhesive 124 attached to the bottom thereof, the thermally conductive material 134 in the through holes 133, the heat-conducting layer 170 and the heat-conducting sheet 270, thereby reducing the temperature of the module card 100.

The module card 100 of the present disclosure is suitable for making flash memory cards commonly available on the market, such as SD cards and micro SD cards, but the present disclosure is not limited thereto.

When the module card of the present disclosure is used in conjunction with a corresponding slot, the heat generated by the die during operation may be easily conducted to an external electronic device. Therefore, the module card of the present disclosure has good heat dissipation capability and is capable of preventing the temperature on the surface thereof from rising continuously.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

1. A module card, comprising:
a substrate having opposing first surface and second surface, a die placement area being defined on the first surface, a plurality of through holes being formed in the substrate and penetrating from the first surface through the substrate to the second surface;
a first die disposed on the first surface of the substrate;
a second die disposed in the die placement area;
an adhesive disposed between the second die and the substrate to attach the second die to the first surface of the substrate;
a plurality of metal contacts disposed on the second surface of the substrate and electrically connected to the first die and the second die;
a heat-conducting layer disposed on the second surface of the substrate for contacting a heat-conducting sheet on a slot; and
a thermally conductive material filled in the through holes and being in contact with the heat-conducting layer and the adhesive.

2. The module card as claimed in claim 1, further comprising:
a molding compound formed on the first surface of the substrate to cover the first die and the second die;

3. The module card as claimed in claim 1, further comprising:
a solder mask formed on the first surface of the substrate and being free of covering the die placement area.

4. The module card as claimed in claim 1, wherein the thermally conductive material is made of gold or copper.

5. The module card as claimed in claim 1, wherein the heat-conducting layer is made of gold or copper.

6. The module card as claimed in claim 1, wherein the adhesive is made of a thermally conductive material.

7. The module card as claimed in claim 1, further comprising:
a solder mask formed on the second surface of the substrate, wherein the heat-conducting layer is exposed from the solder mask.

8. The module card as claimed in claim 1, wherein the first die is a memory die.

9. The module card as claimed in claim 1, wherein the second die is a controller die or a power management die.

10. A combination of a module card and a slot, comprising:
a slot, comprising:
a substrate;
a plurality of metal contacts disposed on and electrically connected to the substrate; and
a heat-conducting sheet disposed on the substrate; and
the module card of claim 1, wherein the module card is inserted into the slot, the metal contacts of the slot being in contact with the metal contacts of the module card respectively, and the heat-conducting sheet of the slot being in contact with the heat-conducting layer of the module card.
